(19) United States
(12) Patent Application Publication
(10) Pub. No.: US 2009/0001427 A1
(43) Pub. Date: Jan. 1, 2009

(54) CHARGE CARRIER BARRIER FOR IMAGE SENSOR

(76) Inventors: James W. Adkisson, Jericho, VT (US); John J. Ellis-Monaghan, Grand Isle, VT (US); Jeffrey P. Gambino, Westford, VT (US); Mark D. Jaffe, Shelburne, VT (US)

Correspondence Address: IBM MICROELECTRONICS;INTELLECTUAL PROPERTY LAW, 1000 RIVER STREET, 972 E, ESSEX JUNCTION, VT, 05452, US

(21) Appl. No.: 11/770,843

(22) Filed: Jun. 29, 2007

(51) Int. Cl. H01L 27/148; H01L 31/113; H01L 31/18

(52) U.S. Cl. 257/229; 257/435; 438/60; 257/E31.084; 257/E27.152

(57) ABSTRACT

A pixel sensor structure, method of manufacture and method of operating. Disclosed is a buffer pixel cell comprising a barrier region for preventing stray charge carriers from arriving at a dark current correction pixel cell. The buffer pixel cell is located in the vicinity of the dark current correction pixel cell and the buffer pixel cell resembles an active pixel cell. Thus, an environment surrounding the dark current correction pixel cell is similar to the environment surrounding an active pixel cell.

### FIELD OF THE INVENTION

The present invention relates generally to electronic devices. More particularly, the invention relates to a charge carrier barrier for an image sensor.

### BACKGROUND OF THE INVENTION

Image sensors, including complementary metal oxide semiconductor (CMOS) image sensors and charge coupled device (CCD) image sensors, are gaining in popularity. In general, semiconductor image sensors are used as imaging components within various types of consumer and industrial products. Non-limiting examples of applications for image sensors include scanners, photocopiers, digital cameras and video telecommunications devices. CMOS image sensors provide advantages in comparison with other types of semiconductor image sensors insofar as CMOS image sensors are generally less expensive to fabricate. CMOS image sensors also generally consume less power.

### BRIEF SUMMARY OF THE INVENTION

The invention includes a structure comprising a substrate; a first region of the substrate comprising a first pixel sensor cell which converts incident electromagnetic radiation into an electrical signal; and, a second region of the substrate comprising: a second pixel sensor cell and a device, the second pixel sensor cell comprising a barrier region which substantially prevents charge carriers generated outside of the second region from arriving at the device.

A method of forming the structure includes providing a substrate; forming in a first region of the substrate a first pixel sensor cell which converts incident electromagnetic radiation into an electrical signal; forming in a second region of the substrate a second pixel sensor cell and a device; and forming a barrier region in the second pixel sensor cell which substantially prevents charge carriers generated outside of the second region from arriving at the device.

Another aspect of the invention includes a CMOS image sensor comprising a substrate; a first region of the substrate comprising a plurality of active pixel cells; and, a second region of the substrate comprising: a buffer pixel cell; a dark current correction pixel cell; and wherein the buffer pixel cell comprises a scavenger region which substantially prevents charge carriers generated outside of the second region from arriving at the dark current correction pixel cell.

Still another aspect of the invention includes a method of operating a CMOS image sensor comprising: converting electromagnetic radiation incident on an active pixel cell into charge carriers during a pre-determined amount of time; and, creating a barrier region in a buffer pixel cell during at least a portion of the pre-determined amount of time, wherein the barrier region substantially prevents charge carriers which overflow from the active pixel cell from arriving at a dark current correction pixel cell.

Yet another aspect of the invention includes a design structure embodied in a machine readable medium used in a design process, the design structure comprising: a substrate; a first region of the substrate comprising a first pixel sensor cell which converts incident electromagnetic radiation into an electrical signal; and, a second region of the substrate comprising: a second pixel sensor cell and a device, the second pixel sensor cell comprising a barrier region which substantially prevents charge carriers generated outside of the second region from arriving at the device.

### BRIEF DESCRIPTION OF THE SEVERAL VIEWS OF THE DRAWINGS

The features of the invention believed to be novel and the elements characteristic of the invention are set forth with particularity in the appended claims. The figures are for illustration purposes only and are not drawn to scale. The invention itself, however, both as to organization and method of operation, may best be understood by reference to the detailed description which follows taken in conjunction with the accompanying drawings in which:

FIG. 1 shows a schematic cross-sectional diagram illustrating embodiments of the invention;

FIGS. 2A-C show schematic cross-sectional diagrams illustrating other embodiments of the invention;

FIG. 3 shows a simplified schematic plan view illustrating a portion of an array layout of a CMOS image sensor according to an embodiment of the invention;

FIG. 4A shows a schematic plan view illustrating an example of pixel sensor cell layout according to an embodiment of the invention, and FIG. 4B shows circuit timing diagrams related to operation of a CMOS image sensor according to embodiments of the invention;

FIG. 5 shows a block diagram illustrating a general-purpose computer system which can be used to implement a circuit and circuit design structure in accordance with an embodiment of the invention; and

FIG. 6 shows a block diagram illustrating an example circuit design flow in accordance with an embodiment of the invention.

### DETAILED DESCRIPTION OF THE INVENTION

Embodiments of the invention are described herein below in terms of a “pixel sensor cell”. It is noted that the term “pixel sensor cell” is used to generally refer to any type of sensor cell which is capable of converting incident electromagnetic radiation into an electrical signal. An example of a pixel sensor cell according to the invention includes a pixel sensor cell that is capable of detecting optical wavelengths of electromagnetic radiation (i.e. visible light) and is commonly referred to as an “image sensor”. An image sensor fabricated using CMOS technology is commonly referred to as a “CMOS image sensor”.

CMOS image sensors typically comprise pixel sensor cells which are used to collect light energy and convert the light energy into readable electrical signals for use within an imaging application. Such pixel sensor cells are referred to as “active pixels”. Each active pixel sensor cell comprises a photosensitive element such as, for example, a photodiode, a pinned photodiode, a photo gate or a photoconductor overlying a doped region of a substrate for accumulating photo-generated charge carriers (e.g. electrons or holes). A read-out circuit is coupled to each active pixel sensor cell for converting the accumulated charge into an electrical signal.

CMOS image sensors also typically comprise other pixel sensor cells from which light energy is prevented from impinging upon. Such pixel sensor cells are referred to as “dark pixels”. An electrical output from a dark pixel sensor cell is typically used to determine a background response of a pixel sensor cell such as for purposes of electrical correction for an active pixel sensor cell output. For example, a total electrical signal that is generated from an active pixel sensor cell includes a component that is due to photo-generated charge carriers and another component that is due to thermally generated charge carriers. In order to read out an electrical signal that includes substantially only the signal component that is due to photo-generated charge carriers, the signal component that is due to thermally generated charge carriers must be removed from the total electrical signal. A dark pixel sensor cell (also referred to hereinafter as a “dark current correction pixel”) can be used to determine an approximate value for the thermally generated charge carrier signal component of an active pixel sensor cell being read out. The thermally generated charge carrier signal component determined from the dark pixel sensor cell can be used to subtract from the total electrical signal so that the remaining electrical signal is mainly due to the photo-generated charge carriers from the active pixel sensor cell.

Obtaining a value for the thermally generated charge carrier signal from the dark current correction pixel that is close to the actual value for the thermally generated charge carrier signal from the active pixel sensor cell is desirable, especially for use of image sensors in low light conditions. When “blooming” occurs, that is, when a relatively large amount of light energy is incident upon an active pixel sensor cell that is adjacent to a dark current correction pixel, at least some charge carriers (e.g. electrons) “overflow” from the active pixel sensor cell and drift over to the dark current correction pixel where the stray charge carriers are collected by the dark current correction pixel which makes it difficult to accurately determine the thermally generated charge carrier signal from the dark current correction pixel. Embodiments of the invention will be described herein after that provide for efficient dark pixel correction.

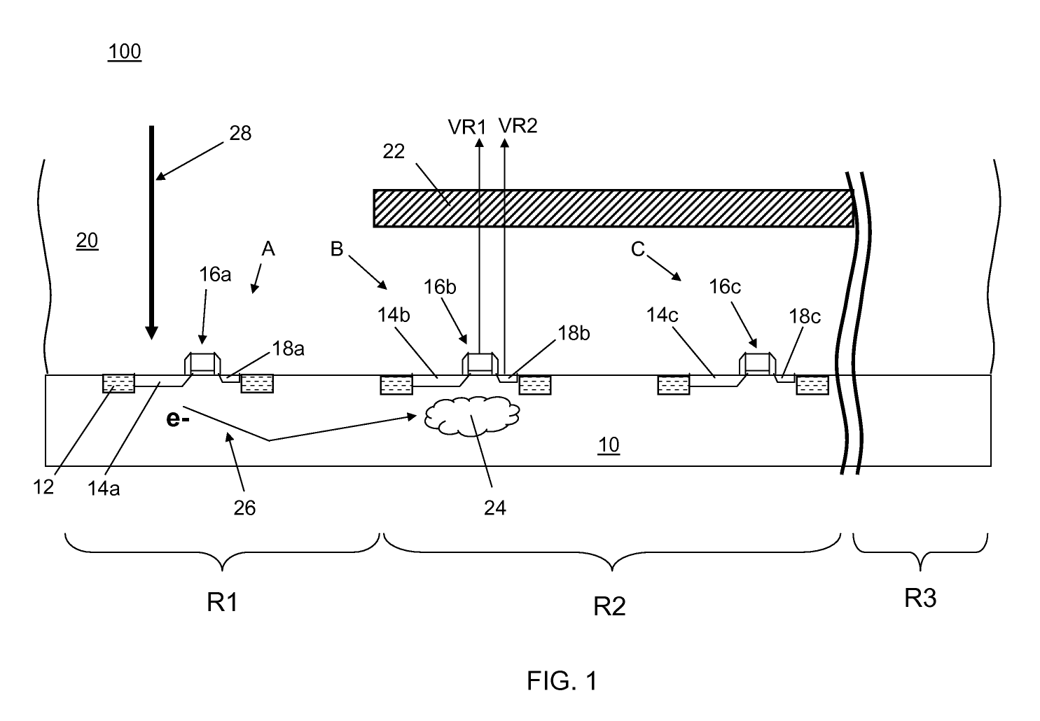

FIG. 1 shows a schematic cross-sectional diagram of a CMOS image sensor 100 in accordance with embodiments of the invention. In order to more clearly focus the description on embodiments of the present invention, features such as inter-level dielectric layers, interconnects as well as lens structures that are used to capture incoming light and color filters that allow for color discrimination have been omitted. It is noted that the pixel sensor cells described herein after with respect to the various embodiments of the present invention include these and other features for proper operation.

Referring to FIG. 1, CMOS image sensor 100 is located on a semiconductor substrate 10. Isolation regions 12 are also located within the semiconductor substrate 10. The semiconductor substrate 10 comprises a first region R1 that comprises an active pixel sensor cell A; a laterally adjacent second region R2 that comprises a buffer dark pixel sensor cell B and a dark current correction pixel C; and, a further laterally adjacent third region R3 that comprises, for example, control circuitry (not shown).

Within pixel sensor cell B, a charge carrier barrier region 24 (“scavenger region”) is shown. Scavenger region 24 illustrated in FIG. 1 generally represents any structure or means which partially, or entirely, prevents charge carriers 26 generated in the first region R1 from drifting over to the dark current correction pixel C. Non-limiting examples of scavenging structures or means will be described herein after with reference to the various embodiments of the invention (e.g. reverse biased photodiode, reverse biased floating diffusion region, etc.). Scavenger region 24 is not limited to only the structures and means described in the various embodiments of the invention. Rather, scavenger region 24 may also comprise other structures and means which attract, collect, trap and/or repel charge carriers 26.

The semiconductor substrate 10 may comprise any of several semiconductor materials. Non-limiting examples of semiconductor materials include silicon, germanium, silicon-germanium alloy, silicon carbide, silicon-germanium carbide alloy and compound semiconductor materials. Non-limiting examples of compound semiconductor materials include gallium arsenide, indium arsenide and indium phosphide semiconductor materials. Typically, the semiconductor substrate 10 comprises a silicon or silicon-germanium alloy semiconductor material that has a thickness from about 1 to about 3 mils. The semiconductor substrate 10 may also comprise an epitaxial layer with a different doping concentration than the bulk substrate.

Within the first region R1, the second region R2 and the third region R3, isolation regions 12 may comprise materials, have dimensions and be formed using methods that are otherwise generally conventional in the semiconductor fabrication art. The isolation regions 12 may include, but are not limited to, local oxidation of silicon (LOCOS) isolation regions, shallow trench isolation regions (i.e., having a depth up to about 5000 angstroms) and deep trench isolation regions (i.e., having a depth up to about 60000 angstroms). Typically, embodiments of the invention use shallow trench isolation regions that are located within shallow isolation trenches. The isolation regions 12 (whether located within shallow isolation trenches or deep isolation trenches) may comprise any of several dielectric materials. Typically included are oxides, nitrides and oxynitrides of silicon, as well as laminates thereof and composites thererof. Oxides, nitrides and oxynitrides of other elements are not excluded.

Within the first region R1 and the second region R2, pixel sensor cells A, B and C each respectively comprise a photodiode 14a/14b/14c; a transfer gate 16a/16b/16c; and, a floating diffusion region 18a/18b/18c. It is noted that the various features of pixel sensor cells A, B and C may comprise materials, may have dimensions and may be formed using methods that are otherwise generally conventional in the semiconductor fabrication art. Transfer gate 16 (TG) may comprise a gate conductor/gate dielectric layer/sidewall spacer. Located in inter-level dielectric layer 20 and substantially over the second region R2 is a layer of opaque material 22 (e.g. metal, dielectric) which is also referred to as a “light shield”. Light shield 22 prevents light incident upon the second region R2 from impinging on pixel sensor cells B and C.

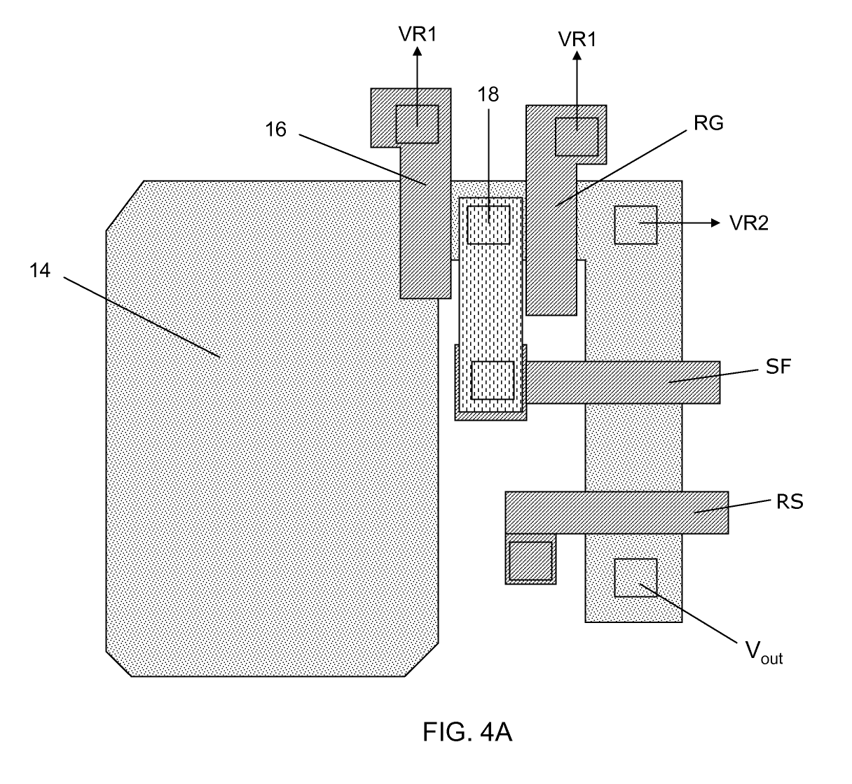

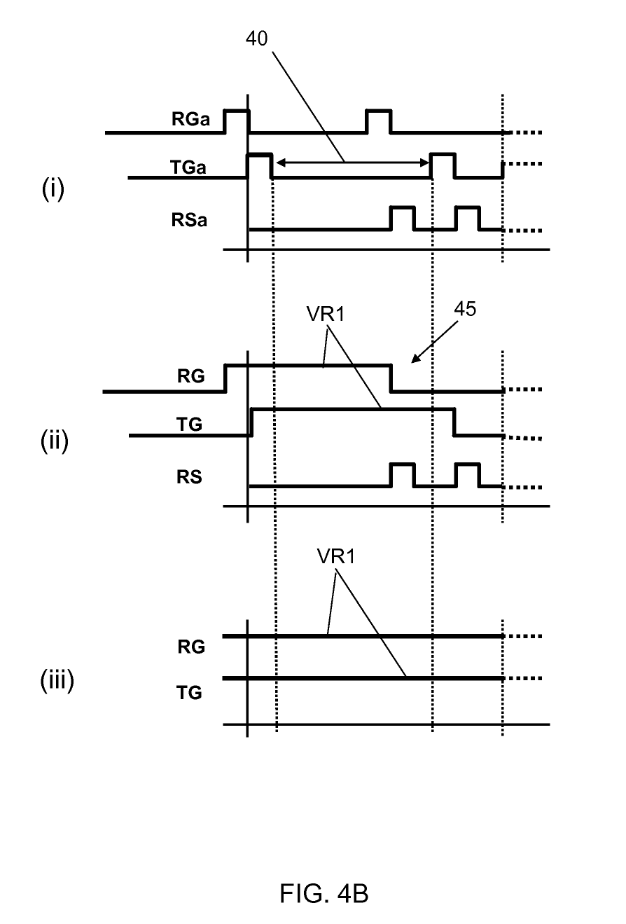

According to an embodiment of the invention, pixel sensor cells A, B, C are basically identical with respect to the photodiode, gate and floating diffusion region. For example, photodiodes 14a/14b/14c are formed using the same processing steps (e.g. photo mask and ion implantation). However, photodiode 14b is reverse biased and coupled to VR2 by coupling transfer gate 16b to VR1 and floating diffusion region 18b to VR2 during at least a portion of a period of time when light integration is occurring in active pixel sensor cell A (as will be described herein after with reference to FIG. 4B). VR1 and VR2 each comprise a substantially constant voltage source such as, for example, a supply voltage Vdd or a reference voltage source that is different than Vdd such as, for example, a voltage that is greater Vdd. VR1 and VR2 can be the same voltage VR1=VR2, or VR1 and VR2 can be different voltages. VR1 is at least a voltage which is sufficient to turn “on” transfer gate 16b. By coupling transfer gate 16b to VR1 and floating diffusion region 18b to VR2, photodiode 14b is reverse biased and is also coupled to VR2 rather than left to be electrically floating as in the case of the photodiode 14a of active pixel sensor cell A. Having photodiode 14b coupled to VR2 maintains a sufficient charge collection capacity for photodiode 14b to collect charge carriers 26 (e.g. electrons) since the photodiode 14b does not decrease to ground potential (which would prevent collection of charge carriers) as is the case for the floating photodiode 14a of active pixel sensor cell A. The charge collection capacity for photodiode 14b can be increased by increasing VR2 (e.g. VR2 greater than Vdd). Stray charge carriers 26 that are generated by incident light 28 onto active pixel sensor cell A are at least partially, or entirely, collected by the photodiode 14b, thus, charge carriers 26 are substantially prevented from reaching the dark current correction pixel C.

By maintaining a substantially consistent pixel cell layout between the first region R1 and second region R2, the array environment of the CMOS image sensor 100 is maintained and perturbation between different pixel sensor cells which are adjacent to each other (e.g. pixel sensor cell A adjacent to pixel sensor cell B, and pixel sensor cell B adjacent to pixel sensor cell C) is reduced. As discussed herein above, by maintaining the environment surrounding the dark current correction pixel C to be similar to the environment surrounding the active pixel sensor cell A results in the value for the thermally generated charge carrier signal from the dark current correction pixel C being close to the actual value for the thermally generated charge carrier signal from the active pixel sensor cell A that is being read. This results in a more consistent noise signal subtraction and improved image quality.

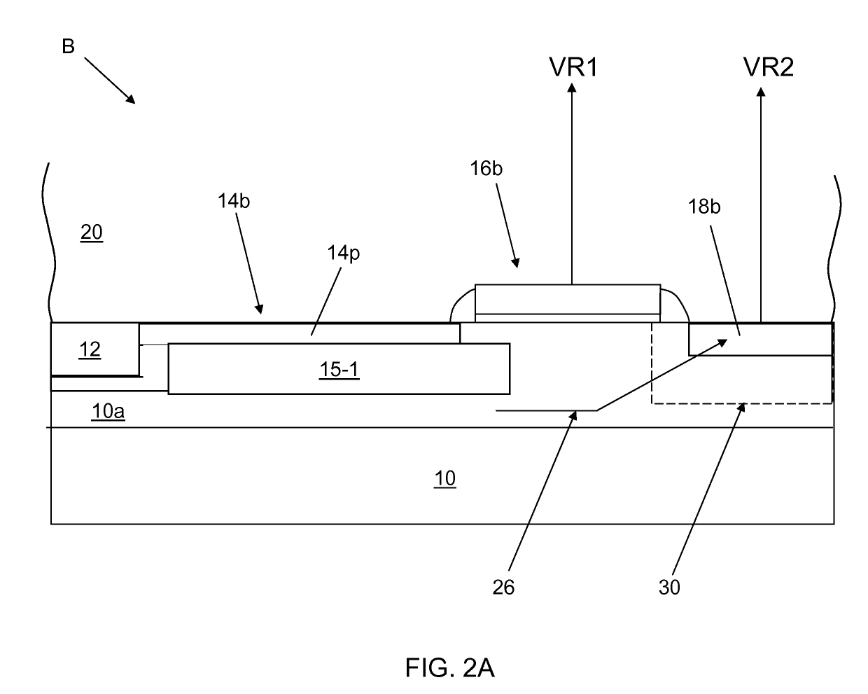

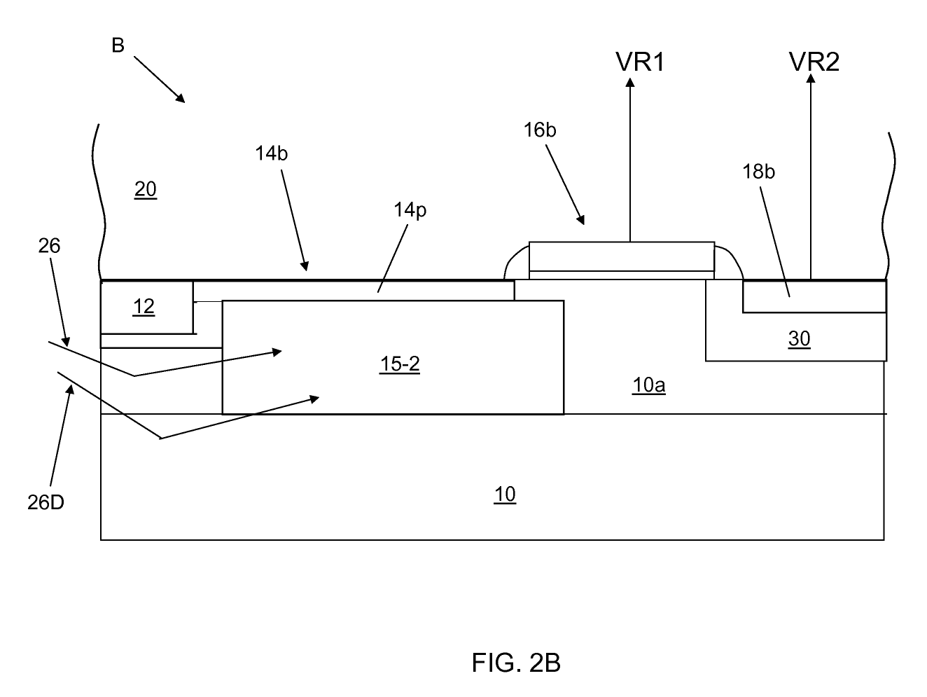

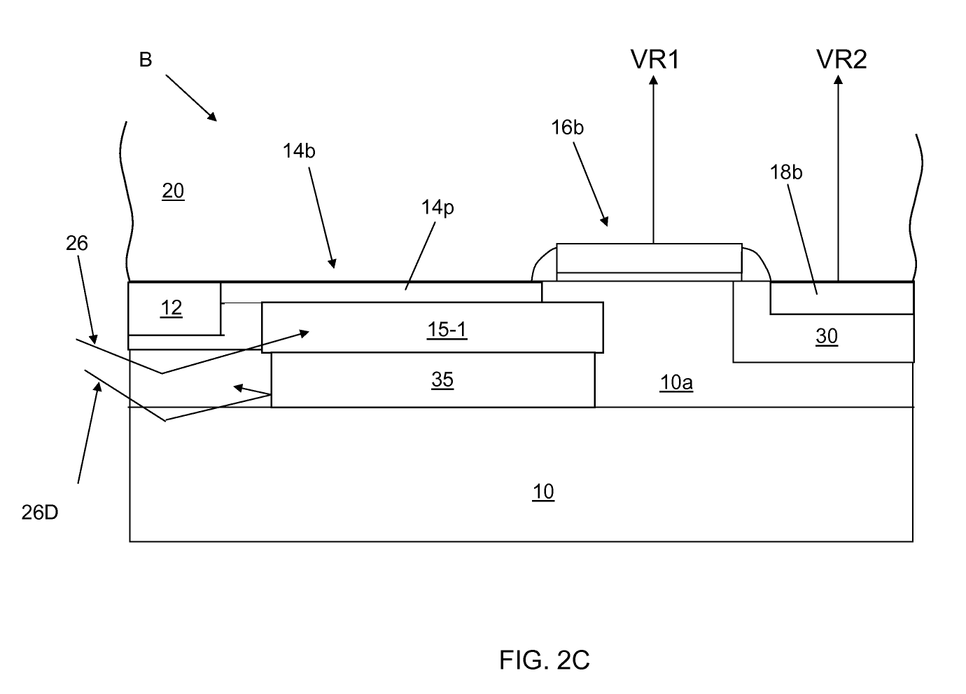

FIGS. 2A-C show expanded schematic cross-sectional diagrams of buffer pixel sensor cell B illustrating other embodiments of the invention. Features that are included in the CMOS image sensor 100 but not shown in detail in FIG. 1 for sake of clarity are shown in FIGS. 2A-C. For example, substrate 10 of a first conductivity type (e.g. p-type) comprises an epitaxial layer 10a of the first conductivity type (e.g. p-type) having a lower doping concentration than substrate 10. Also shown in FIGS. 2A-C is photodiode 14b which comprises a pinning layer 14p of the first conductivity type (e.g. p-type) and a collection well region 15-1 (or 15-2) of an opposite conductivity type (e.g. n-type) than the pinning layer 14p.

Referring to FIG. 2A, another embodiment of the invention is shown where a dopant region 30 (e.g. p-well) of the first conductivity type having a higher dopant concentration than epitaxial layer 10a is not included (illustrated by dashed lines in FIG. 2A) in buffer pixel sensor cell B, however, dopant region 30 is included in active pixel sensor cell A (not shown) and dark current correction pixel C (not shown). Preventing formation of p-well 30 in buffer pixel sensor cell B can be accomplished, for example, by using a masking layer (e.g. photoresist) which has openings in pixel sensor cells A and C to allow p-type dopant atoms to be introduced (e.g. ion implantation) into epitaxial layer 10a to surround floating diffusion regions 18a/18c while the masking layer (not shown) does not have an opening in pixel sensor cell B so the p-type dopant atoms are prevented from being ion implanted into epitaxial layer 10a. Thus, according to the embodiment of the invention shown in FIG. 2A, a substantially consistent pixel cell layout is maintained between the pixel sensor cells A, B and C with only buffer pixel sensor cell B having a difference (i.e. p-well 30 not present) when compared to the other pixel sensor cells A and C.

By eliminating p-well 30 and coupling floating diffusion region 18b (n-type) to VR2 essentially creates a reverse biased photodiode region (i.e. p-epitaxial layer 10a/n-floating diffusion region 18b) which collects stray charge carriers 26 (e.g. electrons). Elimination of p-well 30 from pixel sensor cell B enhances the collection of charge carriers in floating diffusion region 18b compared to when the p-well 30 is present. Floating diffusion region 18b may be coupled to VR2 during at least a portion of a period of time when light integration is occurring in active pixel sensor cell A (as will be described herein after with reference to FIG. 4B). By coupling floating diffusion region 18b to VR2, a sufficient charge collection capacity for floating diffusion region 18b is maintained in order to collect charge carriers 26 since floating diffusion region 18b does not decrease to ground potential (which would prevent collection of charge carriers) as is the case for the floating collection well of active pixel sensor cell A. The charge collection capacity for floating diffusion region 18b can be increased by increasing VR2 (e.g. VR2 greater than Vdd). Stray charge carriers 26 that are generated by incident light 28 onto active pixel sensor cell A are at least partially, or entirely, collected by the floating diffusion region 18b and, thus, stray charge carriers 26 are substantially prevented from reaching the dark current correction pixel C.

Referring to FIG. 2B, yet another embodiment of the invention is shown where buffer pixel sensor cell B comprises a collection well region 15-2 of an opposite conductivity type (e.g. n-type) than the substrate 10 (e.g. p-type) which extends a greater distance into the epitaxial layer 10a than corresponding collection well regions (not shown) in pixel sensor cells A and C. For example, collection well region 15-2 extends entirely through the thickness of epitaxial layer 10a and into an upper portion of substrate 10 as shown in FIG. 2B, whereas collection well regions in pixel sensor cells A and C extend only partially into epitaxial layer 10a (e.g. see collection well region 15-1 shown in FIG. 2A). Deep collection well region 15-2 can be formed, for example, by using the same process steps (e.g. photoresist masking layer and ion implantation) that are used to form n-well regions on substrate 10 so that additional process steps are not required, or additional process steps could be used to form only the deep collection well region 15-2. Collection well regions in pixel sensor cells A and C would be blocked from receiving the n-well implant and, likewise, deep collection well region 15-2 would be blocked from receiving the collection well implant of pixel sensors A and C. Thus, according to the embodiment of the invention shown in FIG. 2B, a substantially consistent pixel cell layout is maintained between the pixel sensor cells A, B and C with only buffer pixel sensor cell B having a difference (i.e. deep collection well region 15-2) when compared to the other pixel sensor cells A and C.

By forming collection well region 15-2 deeper than a typical collection well region of a photodiode (e.g. collection well region of photodiode 14a), deep collection well region 15-2 is capable of collecting stray charge carriers 26D (e.g. electrons) which are present deeper in epitaxial layer 10a or in an upper portion of substrate 10. Transfer gate 16b may be coupled to VR1 and floating diffusion region 18b may be coupled to VR2 during at least a portion of a period of time when light integration is occurring in active pixel sensor cell A (as will be described herein after with reference to FIG. 4B). VR1 and VR2 each comprise a substantially constant voltage source such as, for example, a supply voltage Vdd or a reference voltage source that is different than Vdd such as, for example, a voltage that is greater Vdd. VR1 and VR2 can be the same voltage (e.g. VR1=VR2=Vdd), or VR1 and VR2 can be different voltages. VR1 is at least a voltage which is sufficient to turn “on” transfer gate 16b. By coupling transfer gate 16b to VR1 and floating diffusion region 18b to VR2, photodiode 14b is reverse biased and deep collection well region 15-2 is also coupled to VR2 rather than left to be electrically floating as in the case of the collection well region of active pixel sensor cell A. By having deep collection well region 15-2 coupled to VR2 maintains a sufficient charge collection capacity for deep collection well region 15-2 to collect charge carriers 26, 26D since the deep collection well region 15-2 does not decrease to ground potential (which would prevent collection of charge carriers) as is the case for the floating collection well of active pixel sensor cell A. The charge collection capacity for deep collection well region 15-2 can be increased by increasing VR2 (e.g. VR2 greater than Vdd). Stray charge carriers 26, 26D that are generated by incident light 28 onto active pixel sensor cell A are at least partially, or entirely, collected by the deep collection well region 15-2 and, thus, prevented from reaching the dark current correction pixel C.

Still referring to FIG. 2B, yet another embodiment of the invention is shown where buffer pixel sensor cell B as described herein above with reference to FIG. 2B is modified such that the collection well region 15-2 and the substrate 10 are the same conductivity type (e.g. n-type). Epitaxial layer 10a would still be of an opposite conductivity type (e.g. p-type) than the collection well region 15-2 as described herein above. By using n-type substrate 10 and n-type deep collection well region 15-2, the collection of deep stray charge carriers 26D (e.g. electrons) is further enhanced since n-type substrate 10 is now also coupled to VR2 (and deep charge collection well 15-2) which effectively increases the charge carrier collection capacity of buffer pixel sensor cell B. Stray charge carriers 26, 26D that are generated by incident light 28 onto active pixel sensor cell A are almost entirely, or entirely, collected by the deep collection well region 15-2 and substrate 10, thus, stray charge carriers 26, 26D are substantially prevented from reaching the dark current correction pixel C. Since n-type substrate 10 is common to all pixel sensor cells A, B and C, a substantially consistent pixel cell layout is still maintained between the pixel sensor cells A, B and C with only buffer pixel sensor cell B having a difference (i.e. deep collection well region 15-2) when compared to the other pixel sensor cells A and C.

FIG. 2C shows yet another embodiment of the invention where buffer pixel sensor cell B comprises a doped region 35 (herein after referred to as “reflector region 35”) of an opposite conductivity type (e.g. p-type) than the stray charge carriers 26, 26D (e.g. electrons) being collected. Substrate 10 and epitaxial layer 10a may be the same conductivity type (e.g. p-type) as reflector region 35. Reflector region 35 comprises a dopant (e.g. boron) at a higher dopant concentration (e.g. about 1×10¹⁵ atoms/cm³ to about 1×10¹⁸ atoms/cm³) than a dopant concentration of epitaxial layer 10a (e.g. about 1×10¹⁴ atoms/cm³ to about 1×10¹⁶ atoms/cm³). Reflector region 35 is formed substantially below collector well region 15-1 and may extend from a lower portion of collection well region 15-1 in epitaxial layer 10a to, or into, substrate 10. Reflector region 35 can be formed, for example, by using the same process steps (e.g. photoresist masking layer and ion implantation) that are used to form another p-type region on substrate 10 so that additional process steps would not be required, or additional process steps could be used to form only the reflector region 35. Collection well regions in pixel sensor cells A and C would be blocked from receiving the p-type implant so that reflector region 35 is not formed in pixel sensor cells A and C. Thus, according to the embodiment of the invention shown in FIG. 2B, a substantially consistent pixel cell layout is maintained between the pixel sensor cells A, B and C with only buffer pixel sensor cell B having a difference (i.e. reflector region 35) compared to the other pixel sensor cells A and C.

Collection well region 15-1 collects relatively shallower charge carriers 26 as described herein-above. Since reflector region 35 is coupled to collection well region 15-1 (i.e. photodiode 14b) which is reverse biased, reflector region 35 becomes charged with minority carriers (e.g. electrons) which repels (or “reflects”) stray charge carriers 26D (e.g. electrons) which are present deeper in epitaxial layer 10a or in an upper portion of substrate 10. Stray charge carriers 26, 26D that are generated by incident light 28 onto active pixel sensor cell A are at least partially, or entirely, collected by the collection well region 15-1 or repelled by the reflector region 35, thus, stray charge carriers 26, 26D are prevented from reaching the dark current correction pixel C. A substantially consistent pixel cell layout is still maintained between the pixel sensor cells A, B and C with only buffer pixel sensor cell B having a difference (i.e. reflector region 35) when compared to the other pixel sensor cells A and C.

It should be understood that the various embodiments of the invention described herein above may be implemented each individually or in combination with one or more embodiments. For example, the embodiment of the invention described with reference to FIG. 2A may be implemented individually (i.e. removal of p-well 30) in pixel sensor cell B. In another example, the embodiment described with reference to FIG. 2A (i.e. removal of p-well 30) may be combined with the embodiment described with reference to FIG. 2B (i.e. deep collection well region 15-2) to provide a buffer pixel sensor cell B comprising the features of each of the individual embodiments (i.e. removal of p-well 30 and deep collection well region 15-2). By combining features of different embodiments of the invention, prevention of charge carriers 26 (and 26D) from reaching the dark current correction pixel sensor cell C may be enhanced while still maintaining a substantially consistent pixel cell layout between the pixel sensor cells A, B and C.

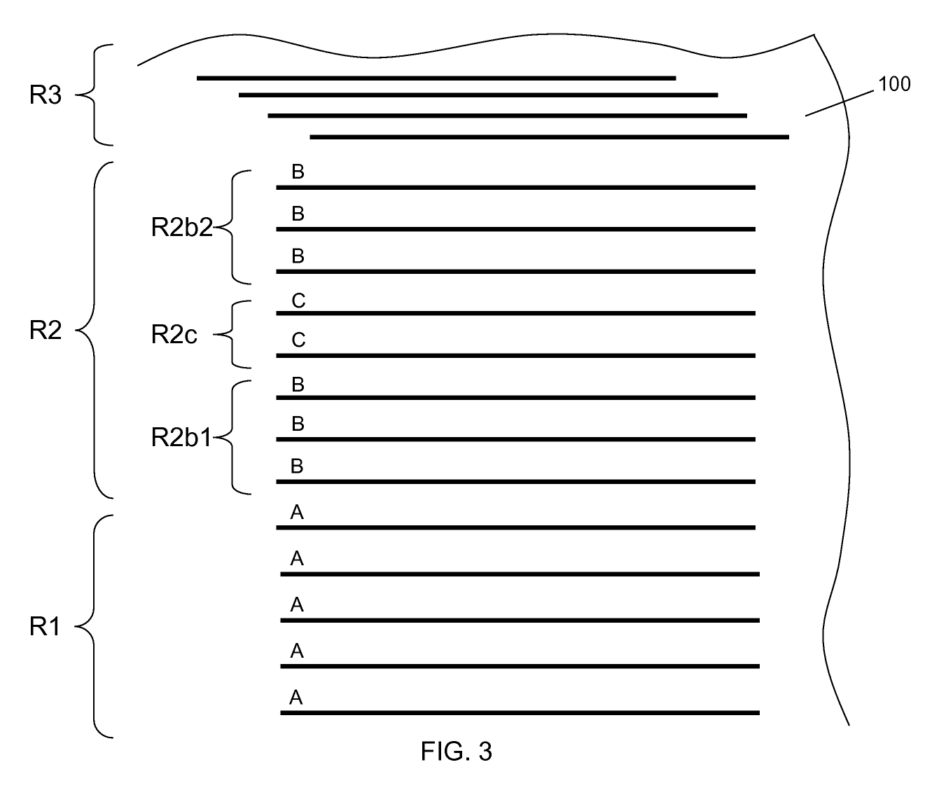

FIG. 3 shows a simplified schematic plan view illustrating a portion of an array layout of CMOS image sensor 100. Pixel sensor cells A, B and C described herein above may be arranged, for example, in rows and/or columns in the array layout of CMOS image sensor 100. Non-limiting examples of such arrangements include, but are not limited to, at least one row of buffer pixels B may be located in region R2b1 between rows of active pixels A in region R1 and at least one row of dark current correction pixels C in region R2c. At least one other row of buffer pixels B may also be located in region R2b2 between the at least one row of dark current correction pixels C in region R2c and control circuitry region R3 in order to also provide a buffer or isolation from charge carriers that may be generated in control circuitry region R3. According to an embodiment of the invention, about one to about ten rows of buffer pixels B are located in region R2b1; about one to about ten rows of dark current correction pixels C are located in region R2c; and, about one to about ten rows of buffer pixels B are located in region R2b2. About one to three, or more, rows of pixel sensor cells that are similar to dark current correction pixels C but whose signals are not read out (herein after referred to as an “inactive dark pixel”) may also be included in the CMOS image sensor 100. For example, inactive dark pixels (not shown) may be included in one or more of the following locations: between regions R1 and R2b1, between regions R2b1 and R2c, between regions R2c and R2b2 or between regions R2b2 and R3. As discussed herein above, by including inactive dark pixels in between regions R2b1/R2c and R2c/R2b2 maintains the environment surrounding the dark current correction pixel C to be similar to the environment surrounding the active pixel sensor cell A.

An aspect of the present invention is also illustrated in FIG. 3 in that greater flexibility to change an array layout of CMOS image sensor 100 is realized. For example, referring to the embodiment of the invention described with reference to FIG. 1, wherein pixel sensor cells A, B and C are substantially similar except for wiring of signals VR1 and VR2 to buffer pixel B, an embodiment of the present invention provides for changing a pixel sensor cell (e.g. dark current correction pixel C) to another type of pixel sensor cell (e.g. buffer pixel B) by making only a relatively minor change to the array layout (e.g. changing only one or more wiring levels). A complete re-design of a substantial part of the CMOS image sensor 100 is not required since the pixel sensor cells A, B and C are substantially similar regardless of their function. Thus, if CMOS image sensor 100 is fabricated and tested according to a first circuit design and it is determined that an additional row of buffer pixels B is required in region R2b1, the circuit design may be modified by changing only one (or more) wiring level so that a row of dark current correction cells C may be converted to buffer pixels B.

FIG. 4A shows a schematic plan view illustrating an example of a four transistor (“4T”) pixel sensor cell layout. According to an embodiment of the invention, pixel sensor cells according to embodiments of the invention may be designed as shown in FIG. 4A. It is noted that the present invention is not limited to a 4T pixel sensor cell layout and that other pixel sensor cell designs (e.g. 3T, 4T-shared, 5T, etc.) may also be contemplated. The pixel sensor cell illustrated in FIG. 4A comprises a photodiode 14, a transfer gate (TG) 16, a floating diffusion region 18, and reference voltages VR1, VR2 as described herein above, and also shown are reset gate RG, amplifier gate (source follower) SF, row select gate RS and output Vout. FIG. 4A is presented to aid in the description related to FIG. 4B.

FIG. 4B shows circuit timing diagrams illustrating various embodiments of the invention related to the operation of CMOS image sensor 100. Timing diagram (i) represents a timing diagram of an active pixel A; timing diagram (ii) represents a timing diagram of a buffer pixel B according to an embodiment of the invention; and, timing diagram (iii) represents a timing diagram of a buffer pixel B according to an another embodiment of the invention. As described herein above, photodiode 14 and floating diffusion region 18 may be coupled to VR2 in order to reverse bias these regions during at least a portion of a period of time 40 when light integration is occurring in active pixel A (see timing diagram (i)). According to an embodiment of the invention illustrated by timing diagram (ii), control circuitry may be used to apply VR1 to transfer gate 16 (TG) and reset gate RG so that both of these transistors are turned “on” resulting in VR2 being coupled to photodiode 14 and floating diffusion region 18. In practical applications, control signals may be synchronized between the active pixel A and the buffer pixel B (e.g. RG turning “off”) in order to minimize noise in the CMOS image sensor 100. This may result in a period of time 45 (due to RG being turned “off”) in the buffer pixel cell B when VR2 is not coupled to photodiode 14 and floating diffusion region 18 (i.e. photodiode 14 and floating diffusion region 18 are not reverse biased) during a corresponding period of time when light integration is still occurring in active pixel A. According to another embodiment of the invention illustrated by timing diagram (iii), VR2 is coupled to photodiode 14 and floating diffusion region 18 in buffer pixel cell B for the entire light integration time 40 of active pixel cell A. For example, VR1 may be coupled to transfer gate 16 (TG) and reset gate RG by direct wiring (e.g. “hard wired”) so transfer gate 16 and reset gate RG are turned “on” for the entire light integration time 40. Thus, VR2 is coupled to photodiode 14 and floating diffusion region 18 (i.e. photodiode 14 and floating diffusion region 18 are reverse biased) for the entire light integration time 40. Likewise, VR1 may be coupled to transfer gate TG and VR2 may be coupled to floating diffusion region 18 by direct wiring (e.g. “hard wired”).

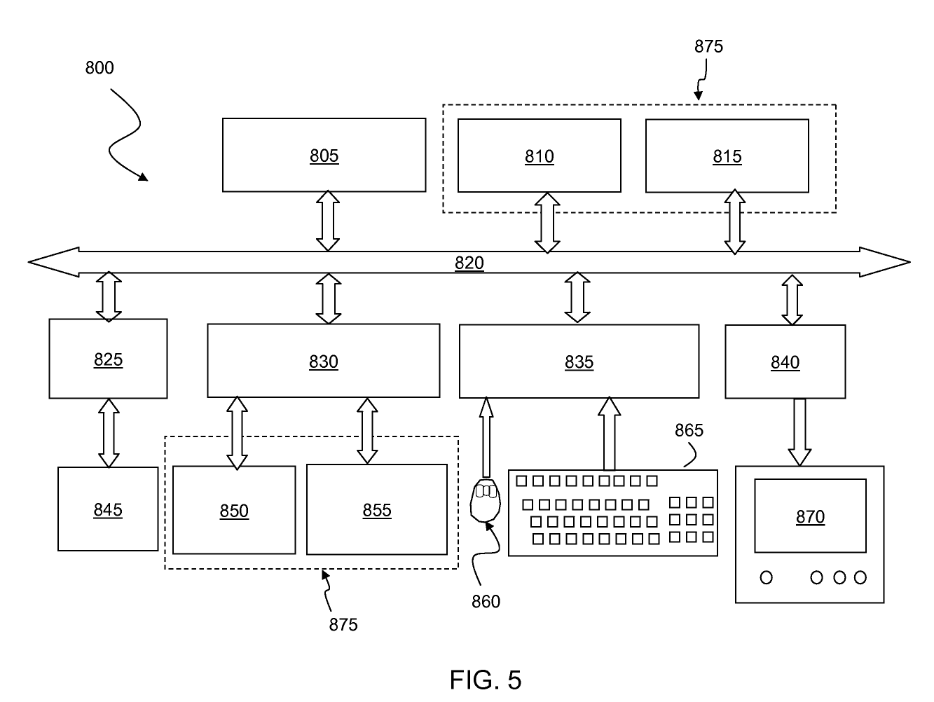

FIG. 5 illustrates a block diagram of a general-purpose computer system which can be used to implement the circuit and circuit design structure described herein. The design structure may be coded as a set of instructions on removable or hard media for use by general-purpose computer. FIG. 5 illustrates a schematic block diagram of a general-purpose computer for practicing the present invention. FIG. 5 shows a computer system 800 which has at least one microprocessor or central processing unit (CPU) 805. CPU 805 is interconnected via a system bus 820 to machine readable media 875, which includes, for example, a random access memory (RAM) 810, a read-only memory (ROM) 815, a removable and/or program storage device 855 and a mass data and/or program storage device 850. An input/output (I/O) adapter 830 connects mass storage device 850 and removable storage device 855 to system bus 820. A user interface 835 connects a keyboard 865 and a mouse 860 to system bus 820, and a port adapter 825 connects a data port 845 to system bus 820 and a display adapter 840 connect a display device 870. ROM 815 contains the basic operating system for computer system 800. Examples of removable data and/or program storage device 855 include magnetic media such as floppy drives, tape drives, portable flash drives, zip drives, and optical media such as CD ROM or DVD drives. Examples of mass data and/or program storage device 850 include hard disk drives and non-volatile memory such as flash memory. In addition to keyboard 865 and mouse 860, other user input devices such as trackballs, writing tablets, pressure pads, microphones, light pens and position-sensing screen displays may be connected to user interface 835. Examples of display device 870 include cathode-ray tubes (CRT) and liquid crystal displays (LCD).

A machine readable computer program may be created by one of skill in the art and stored in computer system 800 or a data and/or any one or more of machine readable medium 875 to simplify the practicing of this invention. In operation, information for the computer program created to run the present invention is loaded on the appropriate removable data and/or program storage device 855, fed through data port 845 or entered using keyboard 865. A user controls the program by manipulating functions performed by the computer program and providing other data inputs via any of the above mentioned data input means. Display device 870 provides a means for the user to accurately control the computer program and perform the desired tasks described herein.

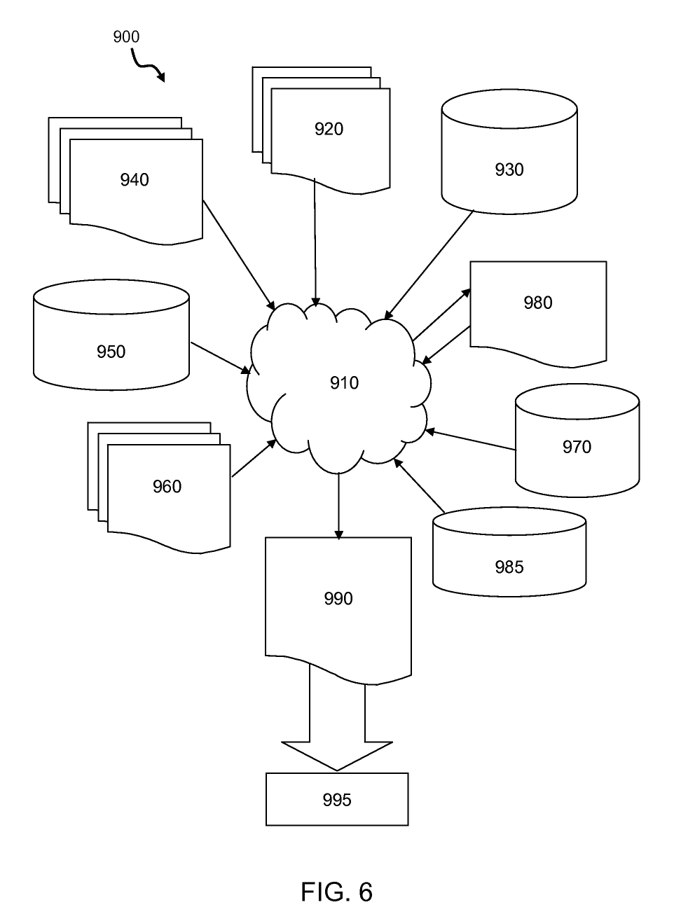

FIG. 6 illustrates a block diagram showing an example design flow 900. Design flow 900 may vary depending on the type of IC being designed. For example, a design flow 900 for building an application specific IC (ASIC) will differ from a design flow 900 for designing a standard component. Design structure 920 is an input to a design process 910 and may come from an IP provider, a core developer, or other design company. Design structure 920 comprises circuit 100 in the form of schematics or HDL, a hardware-description language, (e.g., Verilog, VHDL, C, etc.). Design structure 920 may be on one or more of machine readable medium 875 as shown in FIG. 5. For example, design structure 920 may be a text file or a graphical representation of circuit 100. Design process 910 synthesizes (or translates) circuit 100 into a netlist 980, where netlist 980 is, for example, a list of wires, transistors, logic gates, control circuits, I/O, models, etc. and describes the connections to other elements and circuits in an integrated circuit design and recorded on at least one of machine readable medium 875.

Design process 910 includes using a variety of inputs; for example, inputs from library elements 930 which may house a set of commonly used elements, circuits, and devices, including models, layouts, and symbolic representations, for a given manufacturing technology (e.g. different technology nodes, 32 nm, 45 nm, 90 nm, etc.), design specifications 940, characterization data 950, verification data 960, design rules 970, and test data files 985, which may include test patterns and other testing information. Design process 910 further includes, for example, standard circuit design processes such as timing analysis, verification tools, design rule checkers, place and route tools, etc. One of ordinary skill in the art of integrated circuit design can appreciate the extent of possible electronic design automation tools and applications used in design process 910 without deviating from the scope and spirit of the invention.

Ultimately design process 910 translates CMOS image sensor 100, along with the rest of the integrated circuit design (if applicable), into a final design structure 990 (e.g., information stored in a GDS storage medium). Final design structure 990 may comprise information such as, for example, test data files, design content files, manufacturing data, layout parameters, wires, levels of metal, vias, shapes, test data, data for routing through the manufacturing line, and any other data required by a semiconductor manufacturer to produce CMOS image sensor 100. Final design structure 990 may then proceed to a stage 995 of design flow 900, where stage 995 is, for example, where final design structure 990 proceeds to tape-out, is released to manufacturing, is sent to another design house or is sent back to the customer.

While there has been shown and described what is considered to be preferred embodiments of the invention, it will, of course, be understood that various modifications and changes in form or detail could readily be made without departing from the spirit of the invention. It is therefore intended that the invention be not limited to the exact forms described and illustrated, but should be constructed to cover all modifications that may fall within the scope of the appended claims.

1. A structure comprising:
a substrate;
a first region of the substrate comprising a first pixel sensor cell which converts incident electromagnetic radiation into an electrical signal; and,
a second region of the substrate comprising:
a second pixel sensor cell and a device, the second pixel sensor cell comprising a barrier region which substantially prevents charge carriers generated outside of the second region from arriving at the device.

2. The structure of claim 1, wherein the device comprises a third pixel sensor cell.

3. The structure of claim 1, wherein the charge carriers are generated by the first pixel sensor cell.

4. The structure of claim 1, wherein the first and second pixel sensor cells are substantially similar.

5. The structure of claim 1, wherein the second pixel sensor cell is located between the first pixel sensor cell and the device.

6. The structure of claim 1, wherein the barrier region is coupled to a voltage source VR.

7. The structure of claim 6, wherein VR is equal to or greater than a supply voltage Vdd.

8. The structure of claim 1, wherein the barrier region comprises a reverse biased photodiode.

9. The structure of claim 1, wherein the barrier region comprises a reverse biased floating diffusion region.

10. The structure of claim 1, wherein the first pixel sensor cell comprises a floating diffusion region formed within a dopant region of an opposite conductivity type than the floating diffusion region, and wherein a corresponding dopant region is not present in the second pixel sensor cell.

11. The structure of claim 1, wherein the first pixel sensor cell comprises a first collection well region extending a first depth into the substrate, and wherein the barrier region comprises a second collection well region extending a second depth greater than the first depth into the substrate.

12. The structure of claim 11, wherein the second collection well region and the substrate are the same conductivity type.

13. The structure of claim 11, wherein the second collection well region and the substrate are different conductivity types.

14. The structure of claim 1, wherein the barrier region comprises a dopant region of an opposite conductivity type than the conductivity type of the charge carriers located substantially below a collection well region.

15. The structure of claim 1 further comprising a layer of opaque material located in an electromagnetic radiation path substantially over at least the second pixel sensor cell which prevents incident electromagnetic radiation from impinging on the second pixel sensor cell.

16. A method comprising:
providing a substrate;
forming in a first region of the substrate a first pixel sensor cell which converts incident electromagnetic radiation into an electrical signal;
forming in a second region of the substrate a second pixel sensor cell and a device; and
forming a barrier region in the second pixel sensor cell which substantially prevents charge carriers generated outside of the second region from arriving at the device.

17. The method of claim 16, wherein the device comprises a third pixel sensor cell.

18. The method of claim 16, wherein the step of forming in the first region and the step of forming in the second region each comprises forming a photosensitive region, forming a charge transfer device and forming a floating diffusion region in the first and second pixel sensor cells using the same process steps, respectively.

19. The method of claim 16, wherein the step of forming in the second region comprises forming the second pixel sensor cell between the first pixel sensor cell and the device.

20. The method of claim 16, wherein the step of forming the barrier region comprises coupling the barrier region to a voltage source VR.

21. The method of claim 20, wherein the step of forming the barrier region comprises coupling the barrier region to a voltage source VR that is equal to or greater than a supply voltage Vdd.

22. The method of claim 16, wherein the step of forming the barrier region comprises forming a reverse biased photodiode.

23. The method of claim 16, wherein the step of forming the barrier region comprises forming a reverse biased floating diffusion region.

24. The method of claim 16, wherein the step of forming in the first region comprises forming in the first pixel sensor cell a floating diffusion region within a dopant region of an opposite conductivity type than the floating diffusion region, and wherein the step of forming in the second region comprises forming in the second pixel sensor cell a floating diffusion region and not forming a corresponding dopant region.

25. The method of claim 16, wherein the step of forming in the first region comprises forming in the first pixel sensor cell a first collection well region extending a first depth into the substrate, and wherein the step of forming the barrier region comprises forming a second collection well region extending a second depth greater than the first depth into the substrate.

26. The method of claim 16, wherein the step of forming the barrier region comprises forming a dopant region of an opposite conductivity type than the conductivity type of the charge carriers located substantially below a collection well region.

27. The method of claim 16 further comprising a step of forming a layer of opaque material in an electromagnetic radiation path substantially over at least the second pixel sensor cell which prevents incident electromagnetic radiation from impinging on the second pixel sensor cell.

28. A CMOS image sensor comprising:
a substrate;
a first region of the substrate comprising a plurality of active pixel cells; and,
a second region of the substrate comprising:
a buffer pixel cell;
a dark current correction pixel cell; and
wherein the buffer pixel cell comprises a scavenger region which substantially prevents charge carriers generated outside of the second region from arriving at the dark current correction pixel cell.

29. The CMOS image sensor of claim 28, wherein the active and buffer pixel cells are substantially similar.

30. The CMOS image sensor of claim 28, wherein the buffer pixel cell is located between the plurality of active pixel cells and the dark current correction pixel cell.

31. The CMOS image sensor of claim 30 further comprising a plurality of buffer pixel cells located between the plurality of active pixel cells and the dark current correction pixel cell.

32. The CMOS image sensor of claim 28 further comprising another buffer pixel cell between the dark current correction pixel cell and a third region of the substrate.

33. The CMOS image sensor of claim 28, wherein the scavenger region comprises a reverse biased photodiode.

34. The CMOS image sensor of claim 28, wherein the scavenger region comprises a reverse biased floating diffusion region.

35. The CMOS image sensor of claim 28, wherein at least one of the plurality of active pixel cells comprises a floating diffusion region formed within a dopant region of an opposite conductivity type than the floating diffusion region, and wherein a corresponding dopant region is not present in the buffer pixel cell.

36. The CMOS image sensor of claim 28, wherein at least one of the plurality of active pixel cells comprises a first collection well region extending a first depth into the substrate, and wherein the scavenger region comprises a second collection well region extending a second depth greater than the first depth into the substrate.

37. The CMOS image sensor of claim 36, wherein the second collection well region and the substrate are the same conductivity type or are different conductivity types.

38. The CMOS image sensor of claim 28, wherein the scavenger region comprises a dopant region of an opposite conductivity type than the conductivity type of the charge carriers located substantially below a collection well region.

39. The CMOS image sensor of claim 28 further comprising a layer of opaque material located in an electromagnetic radiation path substantially over at least the buffer pixel cell which prevents incident electromagnetic radiation from impinging on the buffer pixel cell.

40. A method of operating a CMOS image sensor comprising:
converting electromagnetic radiation incident on an active pixel cell into charge carriers during a pre-determined amount of time; and,
creating a barrier region in a buffer pixel cell during at least a portion of the pre-determined amount of time, wherein the barrier region substantially prevents charge carriers which overflow from the active pixel cell from arriving at a dark current correction pixel cell.

41. The method of claim 40, wherein the step of creating the barrier region comprises creating the barrier region during the entire pre-determined amount of time.

42. A design structure embodied in a machine readable medium used in a design process, the design structure comprising:
a substrate;
a first region of the substrate comprising a first pixel sensor cell which converts incident electromagnetic radiation into an electrical signal; and,
a second region of the substrate comprising:
a second pixel sensor cell and a device, the second pixel sensor cell comprising a barrier region which substantially prevents charge carriers generated outside of the second region from arriving at the device.

43. The design structure of claim 42, wherein the design structure comprises a netlist.

44. The design structure of claim 42, wherein the design structure resides on a GDS storage medium.

45. The design structure of claim 42, wherein the design structure comprises test data files, characterization data, verification data or design specifications.
